(19) United States
(12) Patent Application Publication
(10) Pub. No.: US 2004/0018450 A1
(43) Pub. Date: Jan. 29, 2004

(54) Method for transferring patterns

(75) Inventors: Cheng-Yu Fang, Hsin-Chu City (TW); Chih-Hsien Huang, Hsin-Chu City (TW); Lawrence Lin, Chung-Ho (TW); Jui-Tsen Huang, Taipei City (TW)

Correspondence Address: LOWE, HAUPTMAN, GOPSTEIN & BERNER, LLP, Suite 310, 1700 Diagonal Road, Alexandria, VA, 22314, US

(73) Assignee: UNITED MICROLECTRONICS CORP.

(21) Appl. No.: 10/201,986

(22) Filed: Jul. 25, 2002

(51) Int. Cl. G03F 7/20; G03F 7/40

(52) U.S. Cl. 430/313; 430/316; 430/317

(57) ABSTRACT

A method for transferring patterns. After a patterned photoresist is formed on a substrate, the patterned photoresist is hardened, and the pattern of the hardened patterned photoresist is transferred into the substrate. Moreover, a popular method to harden is the silylation process, it is acceptable to only harder the top of the patterned photoresist or to harden both the top and the sidewall of the patterned photoresist. Besides, it is optional to change the thickness and the critical dimension of the patterned photoresist before it is hardened. Significantly, because the etch resistance of hardened patterned photoresist is higher than that of the non-hardened patterned photoresist, the method can improve any defect induced by etched photoresist during the pattern transferring process. Similarly, because a thinner non-hardened photoresist is available for the method, a smaller critical dimension of the patterned photoresist is available for the method while the photolithography technology being not improved.

### BACKGROUND OF THE INVENTION

1. Field of the Invention

The invention relates to the method for transferring patterns. Specifically, the invnetion is related to the method which effectively prevents the defects induced by damaged photoresist during the pattern transferring process.

2. Description of the Prior Art

The conventional pattern transfer process has the following essential steps, are shown in FIG. 1A through FIG. 1C: forming photoresist layer 12 on object layer 11 which is located on substrate 10, patterning photoresist layer 12 to form pattern photoresist 13, and treating object layer 11 by an etching process, which uses pattern photoresist 13 as a mask, to transfer the pattern of pattern photoresist 13 into object layer 11. In the ideal case, pattern photoresist 13 is not etched by the etching process or the etched quantity is negligible such that the pattern of pattern photoresist 13 is precisely transferred into object layer 11.

However, in the real world, the etched quantity of pattern photoresist 13 usually is irnegligible, specifically while pattern photoresist 13 being enough thin or enough narrow. In the mean time, as shown in FIG. 1D, the shape of pattern photoresist 13 is deformed and the really transferred pattern transferred into object layer 11 is different to the predetermined pattern of the non-deformed pattern photoresist 13.

One conventional method to overcome the defects shown in FIG. 1D is to change the material of photoresist 12. By using photoresist material with high etch resistance, the etched quantity could be effectively reduced and then the deformation of pattern photoresist 12 could be effectively prevented. However, because the material of photoresist layer 11 must have a specific photosensitive and a specific adherence, this is not an easy method, specifically while the high etch resistance photoresist material usually being the high cost photoresist material.

Another conventional method to over the defects shown in FIG. 1D is to increase the thickness of photoresist 1layer 12. By lowering the ratio between the etched pattern photoresist 13 and the original pattern photoresist 13, the effect of etched photoresist could be effectively reduced. However, because the resolution of photolithography is limited, the aspect of available pattern photoresist 13 has an upper limitation. Thus, the increase of thickness of pattern photoresist 13 unavoidably increase the critical dimension of pattern photoresist 13, and the critical dimension of the pattern transferred into object layer 11 also is increased. Significantly, although it is easy and low cost to increase the thickness of pattern photoresist 13, it also increases the critical dimension of formed pattern. Hence, this method is not suitable for precise semiconductor product and precise semiconductor fabrication.

In short, the conventional technologies could not effectively overcome the defects induced by etched photoresist during the pattern transferring process, specifically could not provide a low cost solution to form precise semiconductor product. Hence, a new solution of the defect is desired.

### SUMMARY OF THE INVENTION

One main object of this invention is to prevent the deformed pattern induced by etched photoresist during the pattern transferring process.

Another main object of this invnetion is to provide a pattern transfer method which could form precise semiconductor product.

Still one object of this invention is to improve the etch resistance of pattern photoresist by use of the current hardening technology, such that the unavoidable difficulties of both changing material and increasing thickness could be avoid.

The invention has the following essential steps: forms a patterned photoresist on a substrate, hardens the patterned photoresist, and transfers the pattern of the hardened patterned photoresist into the substrate. Moreover, a popular method to harden the pattern photoresist is the silylation process. It is acceptable to only harder the top of the patterned photoresist or to harden both the top of the sidewall of the patterned photoresist. Besides, it is optional to change the thickness and the critical dimension of the patterned photoresist before it is hardened.

The mechanism of the invention could be summarized as following: because the etch resistance of hardened patterned photoresist is higher than that of the non-hardened patterned photoresist, any defect induced by etched photoresist during the pattern transferring process could be improved. Similarly, because a thinner non-hardened photoresist is available, a smaller critical dimension of the patterned photoresist is available for the method while the photolithography technology being not improved.

### BRIEF DESCRIPTION OF THE DRAWINGS

A more complete appreciation and many of the attendant advantages will be readily obtained as the same becomes better understood by reference to the following detailed description when considered in connection with the accompanying drawings.

FIG. 1A through FIG. 1D qualitatively shows the essential steps of the conventional pattern transfer process and one constantly happened defect;

FIG. 2A through FIG. 2J qualitatively shows the essential steps of one preferred embodiment of the invention and some available amendment of the preferred embodiment; and

FIG. 3 shows the essential flow chart of another preferred embodiment of the invention.

### DESCRIPTION OF THE PREFERRED EMBODIMENT

Regarding to the defects appears while the conventional technology increases the total etch resistance of pattern photoresist by changing material or increasing thickness, the invention emphasizes the following clues:

(a) While the etch resistance of photoresist material being enough larger, the damages induced by etching process could be effectively prevent without increasing the thickness of the pattern photoresist.

(b) While the surface of pattern photoresist being covered by high etch resistance material, the action which the etching process acts into the pattern photoresist could be effectively cancelled by the high etch resistance material and then it is not necessary to change the material of the pattern photoresist.

(c) Because the pattern transfer process practically transfer the pattern of the structure on the substrate into the substrate, it is possible to form the pattern structure by both the pattern photoresist and the high etch resistance material but not only use the photoresist to form the pattern structure.

According to these clues, the invnetion provides a new pattern transfer method which prevent the defects induced by etched photoresist during the pattern transfer method with neither changing photoresist material nor increasing photoresist thickness.

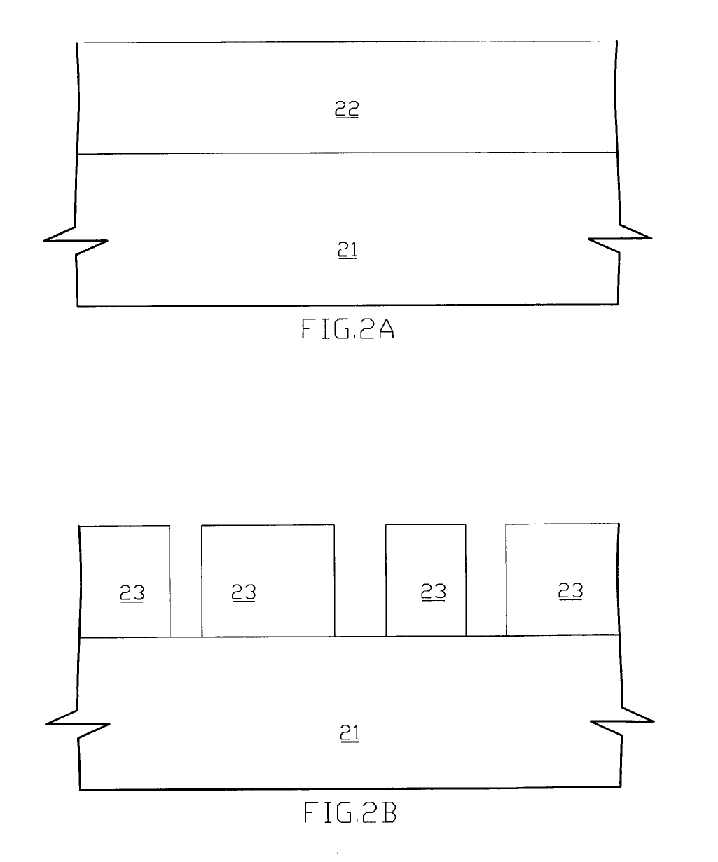

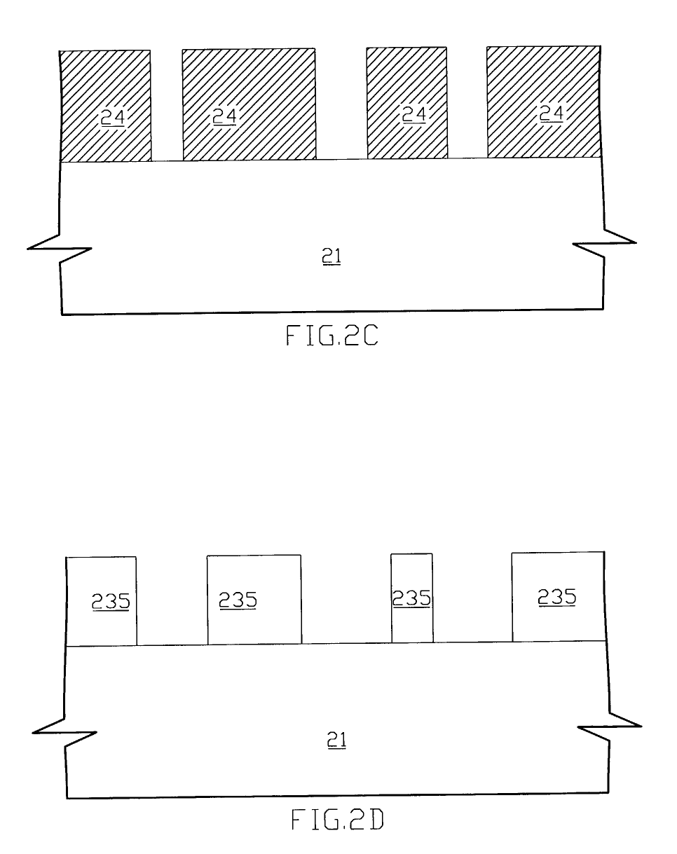

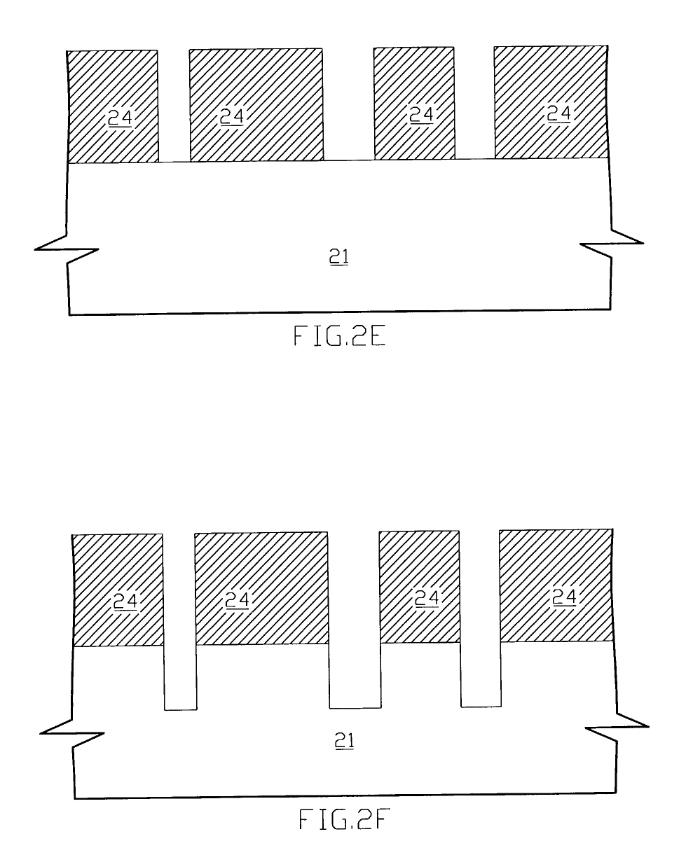

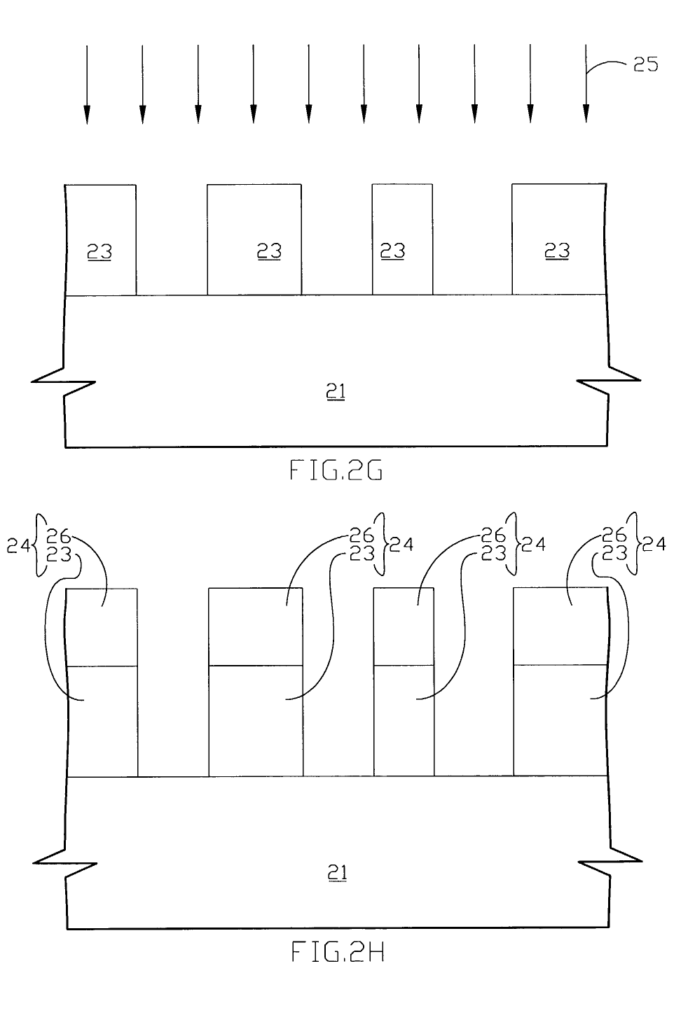

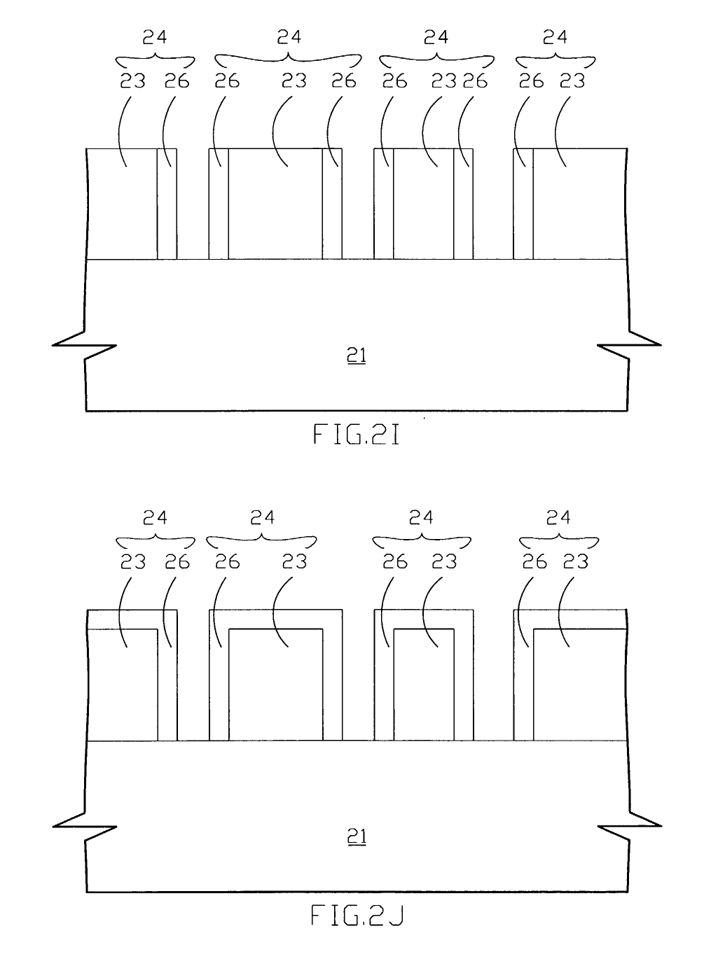

One preferred embodiment of this invention is a pattern transfer method, further is a method for patterning the poly gate or the metal line, as shown in FIG. 2A through FIG. 2F, which at least has the following essential steps:

As shown in FIG. 2A, form photoresist layer 22 on substrate 21.

As shown in FIG. 2B, pattern photoresist layer 22 to form first pattern photoresist 23, wherein first pattern photoresist 23 has numerous first photoresist structures.

As shown in FIG. 2C, perform a hardening process to harden first pattern photoresist 23 and to form second pattern photoresist 24, wherein the etch resistance of second pattern photoresist 24 is higher than the etch resistance of first pattern photoresist 23.

Surely, after the hardening process, the pattern of second pattern photoresist 24 could be different to the pattern of first pattern photoresist 23. Thus, as shown in FIG. 2D and FIG. 2E, it is possible to treat first pattern photoresist 23 for amending the thickness and the critical, which labeled as amended first pattern photoresist 235, before first pattern photoresist 23 is hardened. Thus, the effect that the following hardening process acts on first pattern photoresist 23 is cancelled by amended first pattern photoresist 235. Of course, although FIG. 2S and FIG. 2E show the example that the thickness and width, or critical dimension, of first pattern photoresist 23 is reduced to cancel the increased thickness and increased width which induced by the hardening process, the embodiment is not limited by the example. While the hardening process reducing the thickness and the width, the embodiment could let the thickness and the width, or the critical dimension, of amended first pattern photoresist 235 be larger than that of first pattern photoresist 23.

Obviously, the thickness and the width, or the critical dimension, of first pattern photoresist could be amended by dry etch or wet etch. However, the embodiment is not limited by how the thickness and the width, or the critical dimension, of first pattern photoresist is amended.

As shown in FIG. 2F, pattern substrate 21 by taking use of second pattern photoresist 24.

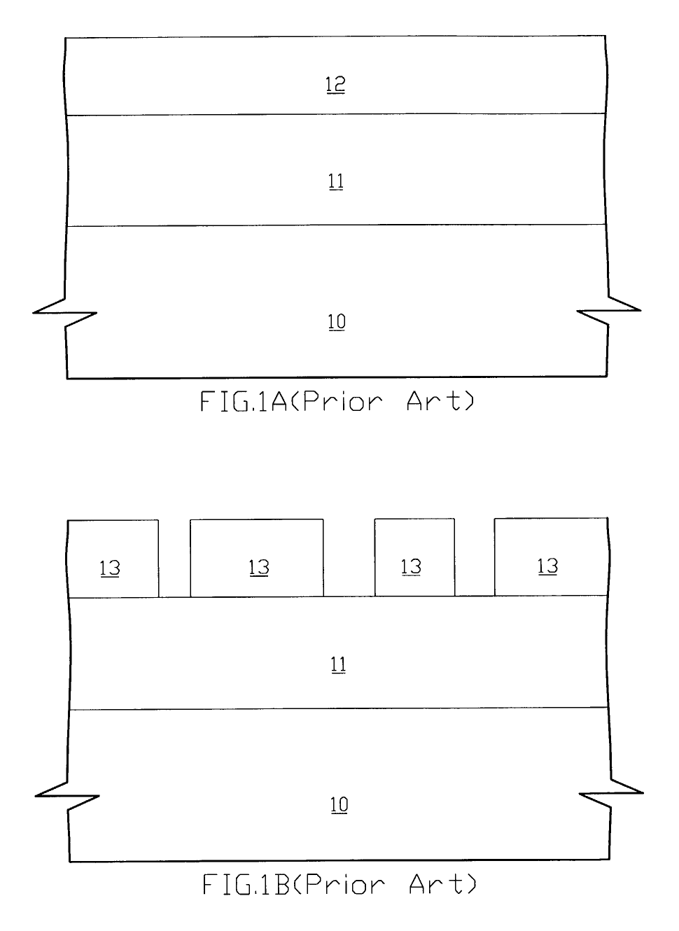

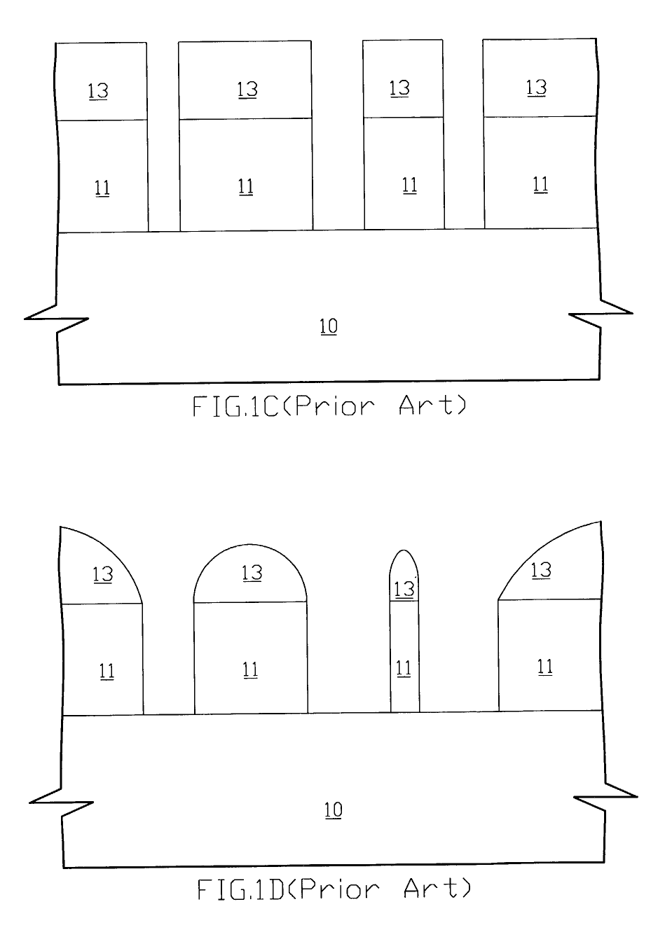

By comparing FIG. 2A through FIG. 2F with FIG. 1A through FIG. 1C, indisputably, the main differences between the embodiment and the conventional technology is the steps shown in FIG. 2C through FIG. 2E.

FIG. 2C shows the step of hardening the material of pattern photoresist to form high etch resistance material without directly changing the material of pattern photoresist. Thus, by perform the hardening process after the pattern photoresist being formed, the pattern transferred into the substrate is provided by a high etch resistance structure. FIG. 2D and FIG. 2E show the steps of forming a pattern photoresist without the required pattern before the pattern photoresist is hardened, such that the deformation induced by process of forming high etch resistance material be cancelled by the difference between the real pattern of the non-hardened pattern photoresist and the really required pattern.

Furthermore, because the distribution of the damages induced by etching process usually is not uniform or isotropic, because the damages tend to appear at the surface, specifically the top ends, of the pattern photoresist, the hardening process could only harden the surface of first pattern photoresist 23, specifically only harden the partial surface where the etched quantity is significantly larger than other parts of the surface. For example, it is possible to let only the top ends of second pattern photoresist 24 be hardened, it also is possible to let only the sidewalls of second pattern photoresist 24 be hardened, it still is possible to let both the top ends and the sidewalls of second pattern photoresist 24 be hardened. Further, it is possible to let whole second pattern photoresist 24 be hardened, it also is possible to form an auxiliary structure on the surface of first pattern photoresist 23 such that second pattern photoresist 24 is the combination of first pattern photoresist 23 and the auxiliary structure.

Note that the embodiment does not limit the details of the hardening process and any process could form second pattern photoresist 24 with higher etch resistance than first pattern photoresist 23 is available. For example, the hardening process could illuminate first pattern photoresist 23 with an UV light to form required second pattern photoresist 24. For example, the hardening process could be the silylation process, wherein the silylation process is a recently developing process which could harden the photoresist, at least the surface of the photoresist, and forms numerous silicon-based layer as products.

Moreover, different etching process and different pattern photoresist induce different etched photoresist defects. Thus, it is possible the etched quantity at the top ends of the pattern photoresist is enough large to let the pattern photoresist be exhausted during the etching process, and it also is possible that the etched quantity at the sidewalls of the pattern photoresist is enough large to let the pattern of pattern photoresist be deformed during the etching process. In this way, as shown in FIG, 2H through FIG. 2J, the embodiment has several amendments. The embodiment could form silicon-based layer 26 at the top ends of first pattern photoresist 23 to prevent the exhaustion of second pattern photoresist 24 while the thickness of first pattern photoresist 23 being enough thin to form pattern in the limitation of photolithography. The embodiment could form silicon-based layer 26 at the sidewalls of first pattern photoresist 23 to prevent deformation of second pattern photoresist 24 while the width of first pattern photoresist 23 being enough narrow to from precise pattern. The embodiment also could form silicon-based layer 26 at both the top ends and the sidewalls of first pattern photoresist 23 to further effectively reduce the deformation of second pattern photoresist 24 during the pattern transferring process.

In general, the silylation temperature of silicon-based layer 26 is lower than the glass transform temperature of first pattern photoresist 23. Thus, the material of patterned photoresists 23/24 would not be liquid-like during the formation of silicon-based layer 26 and then the shape of pattern photoresists 23/24 would not be deformed by the flow of liquid-like material.

Further, there are several ways to form silicon-based layers 26. For example, silicon-based layers being 26 could be formed by illuminating first pattern photoresist 23 with light while the material of first pattern photoresist 23 being the silylatable material. For example, second pattern photoresist 24 could be formed by the reaction between first pattern photoresist 23 and the catalyser for activating the silylation process which is formed on the surface of first pattern photoresist 23. Herein, the available material of first pattern photoresist 23 is chosen form the group consisting of the following: chemical amplification photoresist material, resin-radical photoresist material and polyphenol-radical photoresist material, and the available catalyser is chosen from the group consisting of the following: TMDS, HMDS, ATMS, DMSDMA, and silica sand.

However, because the embodiment only uses the known silylation process to solve the deformation defect induced by etched photoresist during the etching process, it is not necessary to further discuss the details of the used silylation process. For example, the basic information of the silylation process at least has been disclosed by the following references: U.S. Pat. No. 5,427,649 U.S. Pat. No. 6,100,014 U.S. Pat. No. 6,271,072 B1 [symbol] SPIE Vol. 771 Advances in Resist Technology and Processing IV (1987) pp.111-117. For example, the details about how to perform the silylation process with the use of HMDS has been at least disclosed by the following references: U.S. Pat. No. 6,235,448 U.S. Pat. No. 6,168,907 U.S. Pat. No. 6,156,668 U.S. Pat. No. 5,935,732 U.S. Pat. No. 5,838,621 U.S. Pat. No. 5,320,934 U.S. Pat. No. 5,142,043 and U.S. Pat. No. 4,445,572.

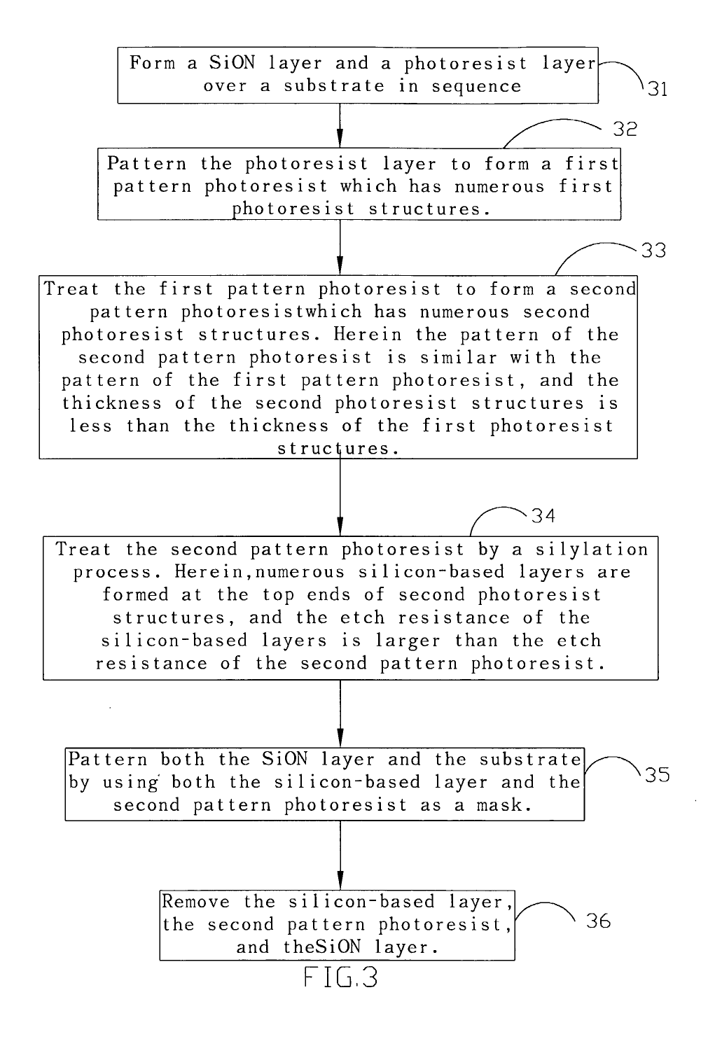

Another preferred embodiment of the invention still is a method for transferring pattern, further is a method for transforming the pattern of the contact hole. By using this embodiment, a smaller contact hole could under the same exposing conditions, and then the process window of the photolithography is increased for both the difficulties of forming the mask and the limitations of the exposing process are effectively improved. As shown in FIG. 3, the embodiment at least has the following steps:

As shown in preparation block 31, form a SiON layer and a photoresist layer over a substrate in sequence.

As shown in pattern block 32, pattern the photoresist layer to form a first pattern photoresist which has numerous first photoresist structures.

As shown in treat block 33, treat the first pattern photoresist to form a second pattern photoresist which has numerous second photoresist structures. Herein the pattern of the second pattern photoresist is similar with the pattern of the first pattern photoresist, and the thickness of the second photoresist structures is less than the thickness of the first photoresist structures.

As shown in silylation block 34, treat the second pattern photoresist by a silylation process. Herein, numerous silicon-based layers are formed at the top ends, even the sidewalls, of second photoresist structures, and the etch resistance of the silicon-based layers is larger than the etch resistance of the second pattern photoresist. Moreover, the critical dimension of the second pattern photoresist is smaller than the critical dimension of the first pattern photoresist.

As shown in transfer block 35, pattern both the SiON layer and the substrate by using both the silicon-based layer and the second pattern photoresist as a mask.

As shown in the removal block 36, remove the silicon-based layer, the second pattern photoresist, and the SiON layer.

From the foregoing it will be appreciated that, although specific embodiments of the invention have been described herein for the purpose of illustration, various modifications may be made without deviating from the spirit and scope of the invention. Accordingly, the invention is not limited except as by the appended claims.

What is claimed is

1. A method for transforming pattern, comprising:
forming a photoresist layer over a substrate;
patterning said photoresist layer to form a first pattern photoresist which has a plurality of photoresist structures;
hardening said first pattern photoresist to form a second pattern photoresist, wherein the etch resistance of said second pattern photoresist is higher than the etch resistance of said first pattern photoresist; and
patterning said substrate by taking use of said second pattern photoresist.

2. The transferring pattern method of claim 1, further comprising a step of treating said first pattern photoresist to change the thickness of the width of each said photoresist structure before the step of hardening said first pattern photoresist.

3. The transferring pattern method of claim 2, both the thickness and the width of each said photoresist structure being reduced.

4. The transferring pattern method of claim 2, said first pattern photoresist being etched to change both the thickness and the width of said photoresist structures.

5. The transferring pattern method of claim 1, only the top end of said first pattern photoresist being hardened.

6. The transferring pattern method of claim 1, only the sidewalls of said first pattern photoresist being hardened.

7. The transferring pattern method of claim 1, both the top ends and the sidewalls of said first pattern photoresist being hardened.

8. The transferring pattern method of claim 1, an auxiliary structure being formed on the surface of said first pattern photoresist while said first pattern photoresist being hardened to form said second pattern photoresist.

9. The transferring pattern method of claim 1, said second pattern photoresist being formed by illuminating said first pattern photoresist with an UV light.

10. The transferring pattern method of claim 1, said second pattern photoresist being formed by a silylation process which forms a plurality of silicon-based layers.

11. The transferring pattern method of claim 10, said silicon-based layers being located at the top ends of said first pattern photoresist.

12. The transferring pattern method of claim 10, said silicon-based layers being located at the sidewalls of said first pattern photoresist.

13. The transferring pattern method of claim 10, said silicon-based layers being located at both the top ends and the sidewalls of said first pattern photoresist.

14. The transferring pattern method of claim 10, the silylation temperature of said silicon-based layer being lower than the glass transform temperature of said first pattern photoresist.

15. The transferring pattern method of claim 10, said silicon-based layers being formed by illuminating said first pattern photoresist with light while the material of said first pattern photoresist being the silylatable material.

16. The transferring pattern method of claim 10, the material of said first pattern photoresist is chosen form the group consisting of the following: chemical amplification photoresist material, resin-radical photoresist material and polyphenol-radical photoresist material.

17. The transferring pattern method of claim 10, the catalyser used by said silylation process is chosen from the group consisting of the following: TMDS, HMDS, ATMS, DMSDMA, and silica sand.

18. A method for transferring pattern, comprising:
forming a SiON layer and a photoresist layer over a substrate in sequence;
patterning said photoresist layer to form a first pattern photoresist which has a plurality of first photoresist structures;
treating said first pattern photoresist to form a second pattern photoresist which has a plurality of second photoresist structures, wherein the pattern of said second pattern photoresist is similar with the pattern of said first pattern photoresist, wherein the thickness of said second photoresist structures is less than the thickness of said first photoresist structures;
treating said second pattern photoresist by a silylation process, wherein a plurality of silicon-based layers are formed at the top ends of said second photoresist structures, wherein the etch resistance of said silicon-based layers is larger than the etch resistance of said second pattern photoresist;
patterning both said SiON layer and said substrate by using both said silicon-based layer and said second pattern photoresist as a mask; and
removing said silicon-based layer, said second pattern photoresist, and said SiON layer.

19. The transferring pattern method of claim 18, the critical dimension of said second pattern photoresist being smaller than the critical dimension of said first pattern photoresist.
